(19) United States
(12) Patent Application Publication
(10) Pub. No.: US 2005/0251997 A1
(43) Pub. Date: Nov. 17, 2005

(54) Method for forming printed circuit board

(75) Inventors: Ching-Fuq Homg, Kaohsiung City (TW); Yung-Hui Wang, Kaohsiung City (TW)

Correspondence Address: BIRCH STEWART KOLASCH & BIRCH, PO BOX 747, FALLS CHURCH, VA, 22040-0747, US

(73) Assignee: Advanced Semiconductor Engineering Inc.

(21) Appl. No.: 11/127,167

(22) Filed: May 12, 2005

(30) Foreign Application Priority Data
May 12, 2004 (TW) 93113283

(51) Int. Cl. H01L 21/4763

(52) U.S. Cl. 29/830; 438/626; 29/831; 29/846; 29/852

(57) ABSTRACT

A method for forming a printed circuit board, and more particularly a method of forming a plated through hole (PTH), a blind via, and a buried via of printed circuit board. The method includes providing a two-layer board having a through hole therein, conformally forming a seed layer on the metal foil and in the through hole, forming a mask on the metal foil, having an opening aligned to the through hole to expose the seed layer on the through hole, forming a conductive layer on the exposed seed layer within the through hole, and removing the mask.

### BACKGROUND OF THE INVENTION

1. Field of the Invention

The present invention relates in general to printed circuit board (PCB) technology, and more particularly, to a method of using a mask to form a plated through hole (PTH), a blind via or a buried via structure wherein the printed circuit board.

2. Description of the Related Art

There is a need to utilize a PTH in a substrate in a manner that facilitates increased wiring density in PCBs.

A PCB typically includes a number of insulation and metal layers selectively patterned to provide metal interconnect lines (referred to herein as “traces”), and a plurality of electronic components mounted on one or more surfaces of the PCB and functionally interconnected through the traces. The routing traces typically carry signals that are transmitted between the electronic components mounted on the PCB. Some PCBs have multiple layers of routing traces to accommodate all of the interconnections.

Traces located within different layers are typically connected electrically by vias formed in the board. A via can be made by making a hole through some or all layers of a PCB and then coating or plating the interior hole surface with an electrically conductive material. A via that connects all layers of the PCB, including the outer layers, is called a “through via.” A via that connects one or more inner layers to an outer layer is a “blind via.”

A PTH can generally be made by making a hole through a two-layer board of a PCB, coating or plating the interior hole surface and the substrate with a seed layer and then electroplating an conductive layer overlying the seed layer. Due to the thickness of the substrate metal foils and the conductive layer however additional planarization of the layer or metal foils is required prior to formation of the seed layer. In addition, because of etching technology limitations, the thicker the conductive metal layers are, the more difficult the formation of wires becomes.

### SUMMARY OF THE INVENTION

Accordingly, the invention provides a novel method for forming a printed circuit board, employed to form narrow wires and uniformly thick conductive layers without metal foils and conductive layer planarization.

A method for forming a printed circuit board. A two-layer board having a hole therein is first provided. A seed layer is then conformally formed on the metal foil and on the wall of the hole. Thereafter, a mask is formed on the metal foil having an opening aligned to the hole to expose the seed layer on the wall of the hole. Finally, a conductive layer is formed on the exposed seed layer within the hole, and the mask is removed.

A method for forming printed circuit board. Further comprises first providing a core substrate having a buried via therein. Next, a second substrate having a metal foil thereon is laminated with the core substrate. Next, a blind via is formed in the second substrate. Next, a seed layer is conformally formed on the metal foil and on the wall of the blind via. Thereafter, a mask is formed on the seed layer of the metal foil, having an opening aligned to the blind via to expose the seed layer. Finally, a conductive layer is formed on the exposed seed layer, and removing the mask.

### DESCRIPTION OF THE DRAWINGS

The present invention will become more fully understood from the detailed description given hereinbelow and the accompanying drawings, given by way of illustration only and thus not intended to be limitative of the present invention.

FIGS. 1 to 7 are cross-sections showing an embodiment of a method for forming a printed circuit board according to the invention.

FIGS. 8 to 15 are cross-sections showing another embodiment of a method for a forming printed circuit board according to the invention.

FIG. 16 is a cross-sectional diagram showing the build-up printed circuit board structure of the invention.

### DETAILED DESCRIPTION OF THE INVENTION

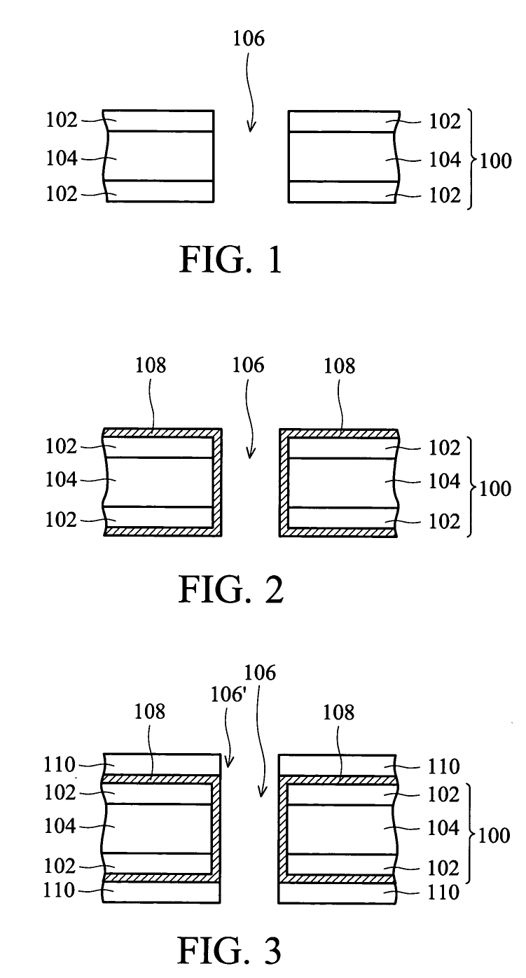

FIGS. 1 to 7 are cross-sections showing a method for forming a printed circuit board according to the invention. First, in FIG. 1, a two-sided metal foil 102 substrate 100 with a middle layer 104 having a through hole 106 therein is provided. The substrate 100 may contain a variety of elements, including, for example, transistors, resistors, capacitors, and other semiconductor elements as are well known in the art. The middle layer 104 can be organic material, fiber reinforcement or particle reinforcement, such as epoxy resin, polyimide, bismaleimide triazine-based(BT), or cyanate ester. The substrate 100 can be a two-layer board or a multi-layer board, and the through hole 106 is formed by laser drilling or mechanism drilling. In order to simplify the diagram, a flat substrate is depicted.

Next, in FIG. 2, a seed layer 108 is conformally formed overlying the substrate 100 surface and along the through hole 106 sidewall by electroless plating, wherein the seed layer 108 is metal, alloy, or laminated metal layer, such as Cu, Sn, , Ni, Cr, Ti, or Cu—Cr alloy. Preferably, the seed layer 108 is copper formed by electroless plating. In the invention, the conductive layer includes the metal foil 102 and the seed layer 108, which has a thickness of about 20 μm.

Next, in FIG. 3 is a key step of the invention, a mask 110, such as a dry film, is attached overlying the seed layer 108 covering the metal foil 102 with an opening 106′ aligned to the through hole 106 to expose the seed layer 108 on the through hole 106. Here, the opening 106′ is formed by lithography and etching processes using the mask 110.

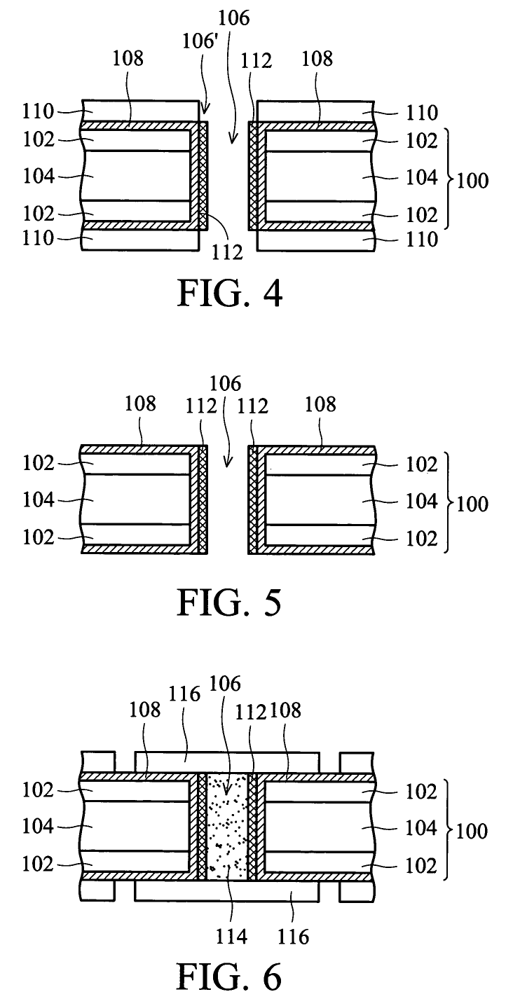

Next, in FIG. 4, a conductive layer 112 is successively formed on the exposed seed layer 108 within the through hole 106, wherein the conductive layer 112 is Cu, Au, Ni, Pd, Ag, Sn, Ni/Pd, Cr/Ti, Ni/Au, Pa/Au, Ni/Pd/Au or the combination thereof. Preferably, the conductive layer 112 is copper formed by electroless plating. In the invention, the seed layer 108 over the metal foil 102 is masked, such that the conductive layer 112 may be thicker only along the through hole 106 sidewall.

In FIG. 5, the mask 110 is removed by ashing or a suitable solution to complete the fabrication of the through hole 106 plated with a conductive layer 112 and a seed layer 108 thereon, which has a total thickness of about 15 μm.

In a preferred embodiment of the invention, a thickness, including a thickness of a metal foil 102, a seed layer 108 and a conductive layer 112, of a conductive metal layer on the substrate 100 is reduced from 25 μm to 20 μm without requiring additional prior planarization. Thus, three drawbacks are improved. First, the conductive metal layer is too thick and requires another thinning process. Second, the thicker the conductive metal layer on the substrate is, the more difficult it is to form small pitch circuits due to the limitations of etching technology. Third, it is very difficult to uniformly control the thickness of the conductive layer at a discontinuity of the seed layer on the metal metal foil and in the through hole.

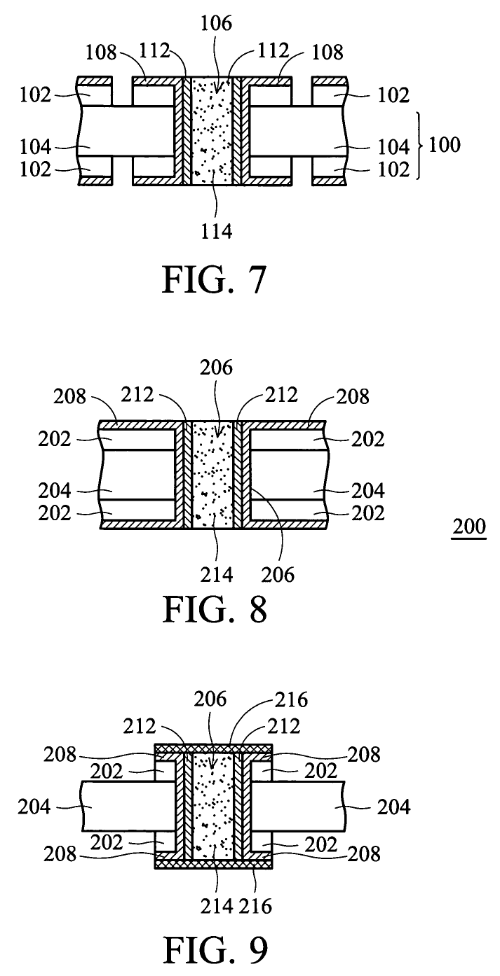

Finally, in FIG. 6, a dielectric filling material 114, such as a resin, a thermal epoxy, or other dielectric material, is filled in the through hole 106. Portions of the dielectric filling material 114 and the seed layer 108 are removed by planarization to form a blind via. Other structures can be formed with the method. In FIG. 7, a photoresist pattern is formed on the structure to form the circuit of the PCB 150.

FIGS. 8 to 15 are cross-sections showing another method for forming a printed circuit board according to the invention. First, in FIG. 8, a core layer is provided using the method as set forth in FIG. 1 to FIG. 6 or other methods well known in the art. The substrate 200 may include a middle layer 204, metal metal foils 202 on the two surfaces of the middle layer 204, a buried via 206 in the middle layer 204 and the metal metal foils 202, a seed layer 208 conformally formed on the metal foils 202 and in the buried via 206, a conductive layer 112 formed on the seed layer 208 over the buried via 206 sidewall, and a dielectric filling material 214 filled in the buried via.

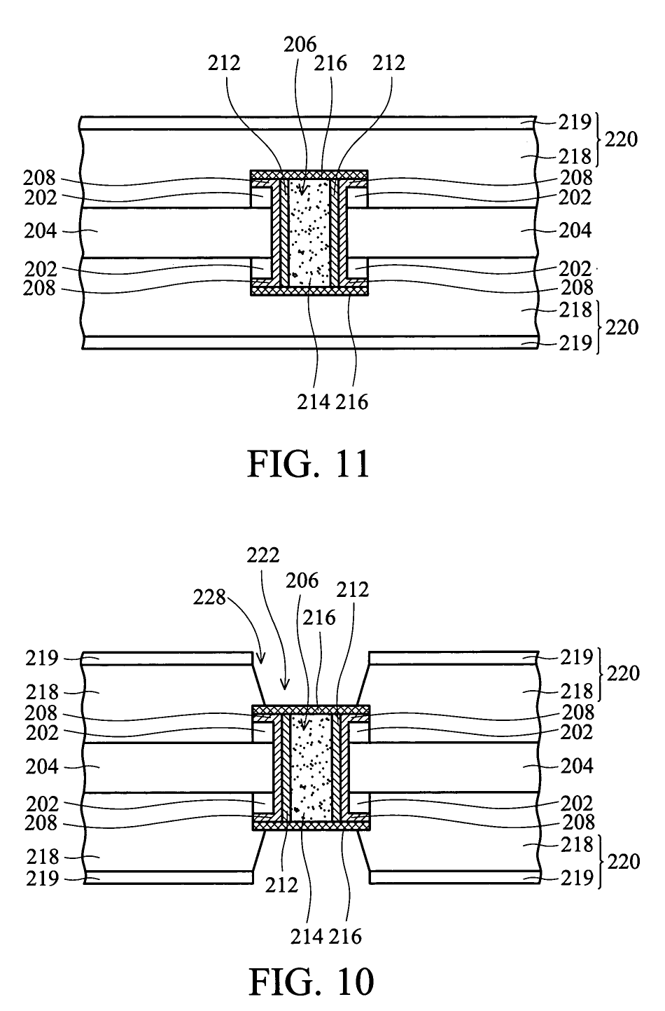

Next, in FIG. 9, another conductive layer 216 is conformally formed overlying the substrate 200 surface by electroless plating and electroplating. The conductive layer 216, the seed layer 208 and the metal foils 202 of the core substrate 200 are then patterned in sequence to form the conductive metal layer. Preferably, the conductive layer 216 is copper. In FIG. 10, a second substrate 220 is laminated on the core substrate 200, wherein the second substrate 220 includes a dielectric layer 218 and a metal metal foil 219. The dielectric layer 218 can be organic material, fiber reinforcement or particle reinforcement, such as epoxy resin, polyimide, bismaleimide triazine-based(BT), or cyanate ester.

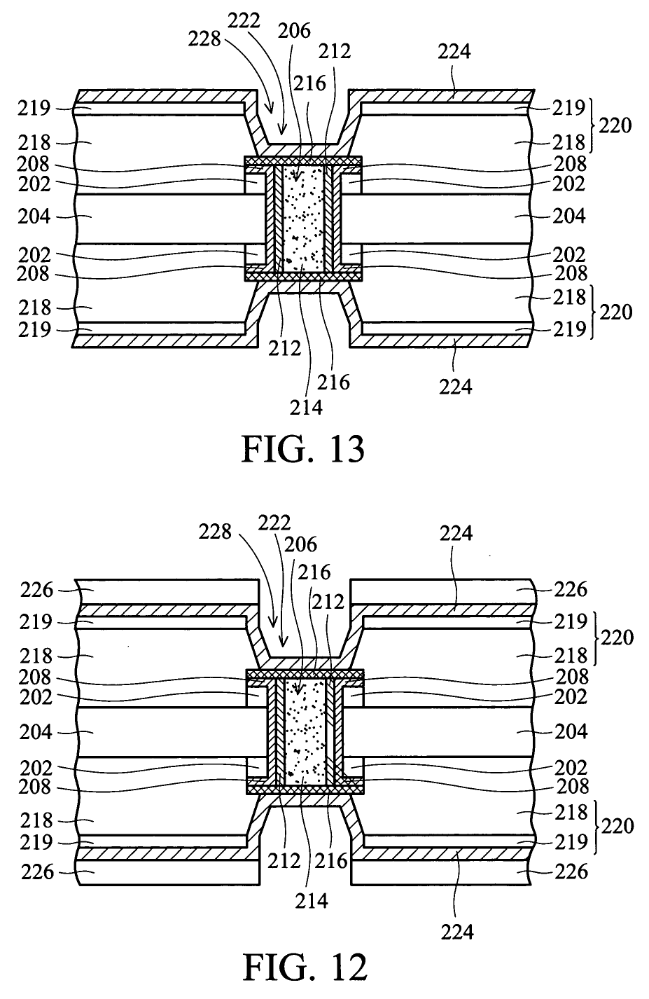

Next, in FIG. 11, a blind via 222 is formed in the second the substrate 220 by laser drilling or mechanical drilling, wherein the blind via 222 is over the patterned conductive layer 216. Next, in FIG. 12, a seed layer 224 is conformally formed on the metal metal foils 219 and on the wall of the blind via 222 to electrically connect the buried via 206, wherein the seed layer 224 is metal, alloy, or laminated metal layer, such as Cu, Sn, , Ni, Cr, Ti, or Cu—Cr alloy. Preferably, the seed layer 224 is copper formed by electroless plating. In the invention, the conductive layer over the second substrate 220 includes the metal foil 219 and the seed layer 224, which has a thickness of about 20 μm. Next, in FIG. 13, a mask 226, such as a dry film, is attached overlying the seed layer 224 covered the metal foil 219 with an opening 228 aligned to the blind via 222 to expose the seed layer 224. Here, the opening 228 is formed by lithography and etching processes using the mask 226.

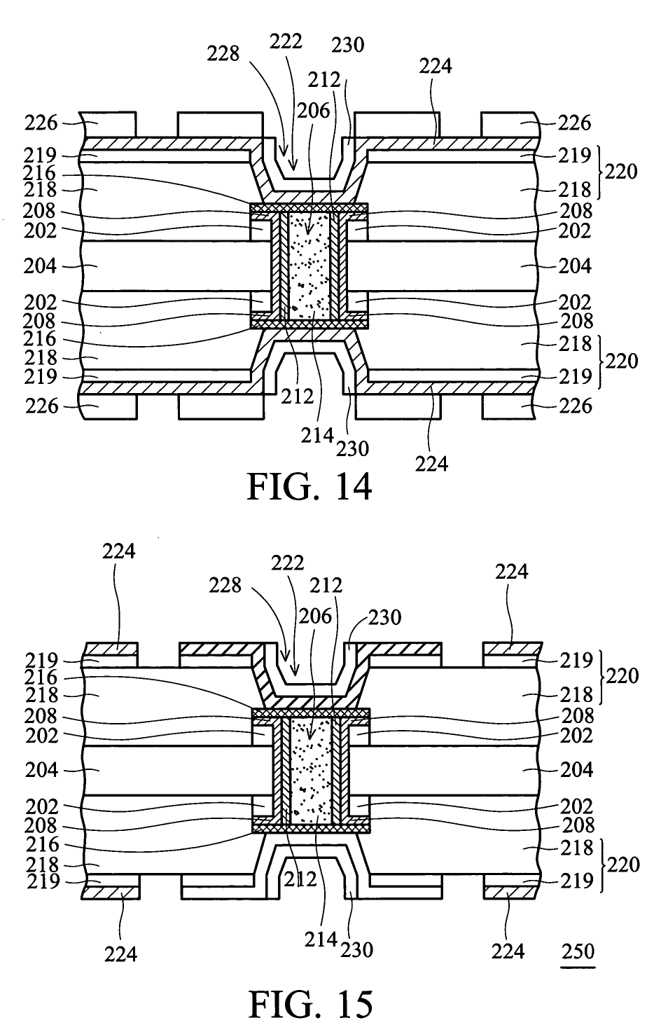

Next, in FIG. 14, a conductive layer 230 is successively formed on the exposed seed layer 224, wherein the conductive layer 230 is Cu, Au, Ni, Pd, Ag, Sn, Ni/Pd, Cr/Ti, Ni/Au, Pa/Au, Ni/Pd/Au or the combination thereof. Preferably, the conductive layer 230 is copper and formed by electroless plating. In the invention, the seed layer 224 over the metal foil 219 is masked such that the conductive layer may be thicker only within the blind via 222. The metal layer formed on the wall of the blind via 222 includes a conductive layer 230 and a seed layer 224 thereon, which totally has a thickness of about 15 μm.

In the preferred embodiment of the invention, a thickness, including a thickness of a metal metal foil 219, a seed layer 224 and a conductive layer (not shown), of a conductive metal layer on the second substrate 220 is reduced from 25 μm to 20 μm without additional prior planarization. Thus, three drawbacks as follows are improved. First, the conductive metal layer is too thick and requires another thinning process. Second, the thicker the conductive metal layer on the substrate is, the more difficult it is to form small pitch circuits due to a limitation of etching technology. Third, it is very difficult to uniformly control the thickness of the conductive layer at a discontinuity of the seed layer on the metal metal foil and on the wall of the blind via.

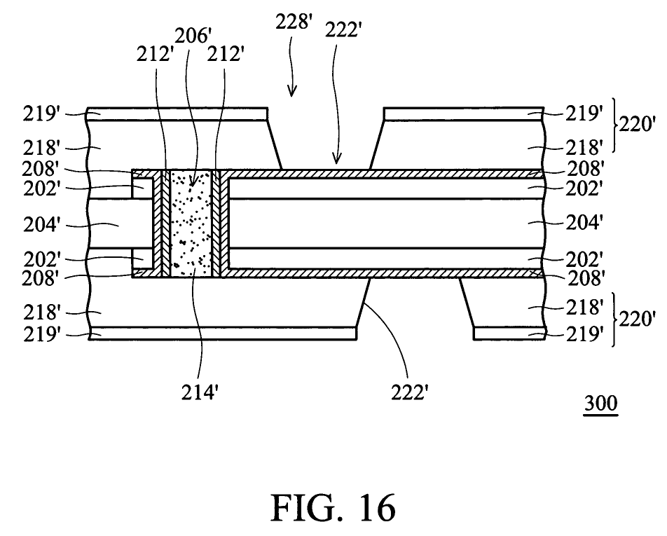

Finally, in FIG. 15, the mask layer 226 is removed with a solution to pattern the metal metal foil 219 and the seed layer 224 on the second substrate 220. The core substrate 200 and the second substrate 220 form a build-up printed circuit board 250. Thus, an electrically conductive build-up printed circuit board (PCB) structure is formed by aligning the buried via 206 with the blind via 222. Other structures can be formed with the method. As shown in FIG. 16, another build-up printed circuit board structure with an offset between the buried via 206′ and the blind via 222′ is formed.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation to encompass all such modifications and similar arrangements.

1. A method for forming a printed circuit board, comprising the steps of:
providing a two-layer board having a hole therein;
conformally forming a seed layer on the metal foil and on the wall of the hole;
forming a mask on the metal foil, having an opening aligned to the hole to expose the seed layer on the wall of the hole;
forming a conductive layer on the exposed seed layer; and
removing the mask.

2. The method as claimed in claim 1, further comprising filling the hole with a material, and planarizing to remove portions of the filling material and the seed layer.

3. The method as claimed in claim 1, further comprising defining the metal foil and the seed layer to form a circuit pattern.

4. The method as claimed in claim 1, wherein the substrate is two-layer board or a multi-layer board.

5. The method as claimed in claim 1, wherein the hole is a through hole or a buried via.

6. The method as claimed in claim 1, wherein the seed layer is formed by electroless method.

7. The method as claimed in claim 1, wherein the mask is a dry film.

8. The method as claimed in claim 1, wherein the mask is formed by lamination.

9. A method for forming printed circuit board, comprising the steps of:
providing a core substrate having a buried via therein;
laminating a second substrate having a metal foil thereon with the core substrate;
forming a blind via in the second substrate;
conformally forming a seed layer on the metal foil and on the wall of the blind via;
forming a mask on the seed layer of the metal foil, having an opening aligned to the blind via to expose the seed layer;
forming a conductive layer on the exposed seed layer; and
removing the mask.

10. The method as claimed in claim 9, wherein the core substrate further comprises a patterned conductive layer on the buried via, and a blind via is aligned to the buried via to from a conductive trace.

11. The method as claimed in claim 9, wherein the second substrate is two-layer board or a multi-layer board.

12. The method as claimed in claim 9, wherein the second substrate comprises copper metal foils.

13. The method as claimed in claim 9, wherein the seed layer is formed by electroless method.

14. The method as claimed in claim 9, wherein the mask is a dry film.

15. The method as claimed in claim 9, wherein the mask is formed by lamination.

16. The method as claimed in claim 9, wherein the mask is removed by solvent.

17. The method as claimed in claim 9, wherein the core substrate is formed by a method as set forth in claim 1.
